(19) United States
(12) Patent Application Publication
(10) Pub. No.: US 2025/0107220 A1
(43) Pub. Date: Mar. 27, 2025

(54) SEMICONDUCTOR DEVICE AND METHOD FOR MANUFACTURING THE SAME

(71) Applicant: SK hynix Inc., Gyeonggi-do (KR)

(72) Inventor: Young Gwang YOON, Gyeonggi-do (KR)

(21) Appl. No.: 18/811,793

(22) Filed: Aug. 22, 2024

(30) Foreign Application Priority Data
Sep. 25, 2023 (KR) 10-2023-0127958

(51) Int. Cl. H01L 27/088; H01L 21/8234; H01L 29/51

(52) U.S. Cl. CPC H10D 84/83; H10D 64/689; H10D 84/0144; H10D 84/038

(57) ABSTRACT

A semiconductor device includes a semiconductor substrate including a first active region and a second active region, a first dielectric layer disposed over the first active region, a second dielectric layer disposed over the second active region, a first gate electrode disposed over the first dielectric layer, and a second gate electrode disposed over the second dielectric layer. The first active region and the second active region have different conductivity types. The first dielectric layer and the second dielectric layer include a same dielectric material. The dipole concentration of the first dielectric layer is different from dipole concentration of the second dielectric layer.

### CROSS-REFERENCE TO RELATED APPLICATION

This patent application claims the priority and benefits of Korean patent application No. 10-2023-0127958, filed on Sep. 25, 2023, the disclosure of which is incorporated by reference in its entirety.

### TECHNICAL FIELD

The technology and embodiments disclosed in the present disclosure generally relate to a semiconductor device and a method for manufacturing the same, and more particularly to a semiconductor device including transistors having different threshold voltages, and a method for manufacturing the same.

### BACKGROUND

As the degree of integration of semiconductor devices increases, the difficulty in designing integrated circuits (ICs) is developing exponentially.

During a process of the development of semiconductor devices, the number of devices included per unit chip area is rapidly increasing while the size of each device is being gradually reduced, and this high degree of integration in semiconductor devices results in increase in the complexity of a fabrication process of an integrated circuit (IC).

For example, as the size of each semiconductor device decreases, it may become impossible to increase a thickness of a dielectric layer to adjust a threshold voltage (Vt), or difficulty may arise in a fabrication process of the semiconductor device.

Accordingly, there is a need for various methods to manufacture semiconductor devices with superior performance while overcoming the limitations caused by a high integration of semiconductor devices.

### SUMMARY

Various embodiments of the present disclosure relate to a semiconductor device including a plurality of transistors with adjusted threshold voltage characteristics.

In accordance with an embodiment of the present disclosure, a semiconductor device may include a semiconductor substrate including a first active region and a second active region; a first dielectric layer disposed over the first active region; a second dielectric layer disposed over the second active region; a first gate electrode disposed over the first dielectric layer; and a second gate electrode disposed over the second dielectric layer. The first active region and the second active region may have different conductivity types, the first dielectric layer and the second dielectric layer may include the same dielectric material, and dipole concentration of the first dielectric layer may be different from dipole concentration of the second dielectric layer.

In an embodiment, each of the first dielectric layer and the second dielectric layer may include a first sub-dielectric layer, and a second sub-dielectric layer disposed over the first sub-dielectric layer.

In accordance with an embodiment, the first sub-dielectric layer and the second sub-dielectric layer may have different silicon concentrations.

In accordance with an embodiment, the first sub-dielectric layer and the second sub-dielectric layer may have different nitrogen concentrations.

In accordance with an embodiment, each of the first dielectric layer and the second dielectric layer may include at least one defect in which dipole diffusion occurs.

In accordance with an embodiment, concentration of the defect of the first dielectric layer and concentration of the defect of the second dielectric layer may be controlled by heat treatment.

In accordance with an embodiment, the first dielectric layer may include a dipole material that is diffused from an upper portion of the first dielectric layer to the first dielectric layer.

In accordance with an embodiment, the dipole material includes at least one of hafnium (Hf), aluminum (Al), lanthanum (La), zirconium (Zr), scandium (Sc), and erbium (Er).

In accordance with an embodiment, the semiconductor substrate may further include: a third active region and a fourth active region; a third gate electrode disposed to overlap the third active region; a fourth gate electrode disposed to overlap the fourth active region; a third dielectric layer disposed between the third active region and the third gate electrode; and a fourth dielectric layer disposed between the fourth active region and the fourth gate electrode. The third active region and the fourth active region may have different conductivity types, the first active region and the third active region may have the same conductivity type, and the third dielectric layer and the fourth dielectric layer may include the same dielectric material.

In accordance with an embodiment, dipole concentration of the third dielectric layer may be different from dipole concentration of the fourth dielectric layer.

In accordance with an embodiment, the first dielectric layer and the third dielectric layer may include different dielectric materials.

In accordance with an embodiment, each of the third dielectric layer and the fourth dielectric layer may include a third sub-dielectric layer, and a fourth sub-dielectric layer disposed over the third sub-dielectric layer.

In accordance with an embodiment, the first dielectric layer, the second dielectric layer, the third dielectric layer, and the fourth dielectric layer may include the same dielectric material.

In accordance with an embodiment of the present disclosure, a method for manufacturing a semiconductor device may include forming a first dielectric layer over a first active region included in a semiconductor substrate; forming a second dielectric layer over a second active region included in the semiconductor substrate; forming a metal pattern layer over the second dielectric layer; forming a dipole material layer over the first dielectric layer and the metal pattern layer; diffusing dipole material from the dipole material layer to the first dielectric layer and the second dielectric layer; forming a first gate electrode overlapping the first dielectric layer; and forming a second gate electrode overlapping the second dielectric layer, wherein the first dielectric layer and the second dielectric layer include the same dielectric material, and the first active region and the second active region have different conductivity types.

In accordance with an embodiment, the method may further include: forming an interlayer dielectric layer over the first active region and the second active region. The forming the first dielectric layer may include: forming a first sub-dielectric layer overlapping the interlayer dielectric layer; and forming a second sub-dielectric layer overlapping the first sub-dielectric layer. The forming the second dielectric layer may include: forming the first sub-dielectric layer overlapping the interlayer dielectric layer; and forming the second sub-dielectric layer overlapping the first sub-dielectric layer.

In accordance with an embodiment, the method may further include: forming a first defect control layer over the first dielectric layer; forming a second defect control layer over the second dielectric layer; performing heat treatment to control defect concentration of the first dielectric layer and defect concentration of the second dielectric layer; and removing the first defect control layer and the second defect control layer.

In accordance with an embodiment, the first defect control layer or the second defect control layer may include a plurality of sub-control layers.

In accordance with an embodiment, the plurality of sub-control layer may include at least one of titanium nitride (TiN), titanium aluminide (TiAl), and polysilicon (Si).

In accordance with an embodiment, the method may further include removing the metal pattern layer.

In accordance with an embodiment, the dipole material includes at least one of hafnium (Hf), aluminum (Al), lanthanum (La), zirconium (Zr), scandium (Sc), and erbium (Er).

It is to be understood that both the foregoing general description and the following detailed description of the embodiments of the present disclosure are illustrative and descriptive and are intended to provide further description of the embodiments as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1 is a cross-sectional view illustrating a semiconductor device in accordance with an embodiment of the present disclosure.

FIG. 2 is a cross-sectional view illustrating a semiconductor device in accordance with another embodiment of the present disclosure.

FIG. 3 is a flowchart illustrating a method for manufacturing a semiconductor device in accordance with an embodiment of the present disclosure.

FIGS. 4A to 4G are cross-sectional views illustrating a method for manufacturing a semiconductor device in accordance with an embodiment of the present disclosure.

FIG. 5 is a flowchart illustrating a method for manufacturing a semiconductor device in accordance with another embodiment of the present disclosure.

FIGS. 6A to 6I are cross-sectional views illustrating a method for manufacturing a semiconductor device in accordance with another embodiment of the present disclosure.

### DETAILED DESCRIPTION

The present disclosure provides embodiments and examples of a semiconductor device including transistors having different threshold voltages and a method for manufacturing the same that may be used in configurations to substantially address one or more technical or engineering issues and to mitigate limitations or disadvantages encountered in some other semiconductor device designs. Various embodiments of the present disclosure relate to a semiconductor device including a plurality of transistors with adjusted threshold voltage characteristics. In recognition of the issues above, the embodiments of the present disclosure provide a semiconductor device that can adjust a threshold voltage of each transistor by adjusting the properties of a dielectric layer.

Reference will now be made in detail to the embodiments of the present disclosure, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, this disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

The drawings may not be necessarily drawn to scale, and in some examples, proportions of at least some of structures in the drawings may be exaggerated to clearly show features of the embodiments. When a multilayer structure having two or more layers is disclosed in the drawings or detailed description, the relative positional relationship or arrangement order of the layers reflects a specific embodiment only and the scope or spirit of the present disclosure is not limited thereto, and it should be noted that the relative positional relationship or arrangement order of the layers may also be changed as necessary. In addition, the drawings or detailed descriptions of a multilayer structure may not reflect all layers present in a particular multilayer structure (e.g., one or more additional layers may be present between two illustrated layers). As a specific example, when a first layer in the multilayer structure is referred to as being “on” or “over” a second layer or “on” or “over” a substrate, the first layer may be directly formed on the second layer or the substrate but may also represent a structure where one or more other layers are present between the first layer and the second layer or between the first layer and the substrate.

Hereinafter, a semiconductor device and a method for manufacturing the same in accordance with embodiments of the present disclosure will be described in detail with reference to the drawings.

A threshold voltage (Vt) may refer to a least voltage required to create a conductive channel for the operation of a transistor included in a semiconductor device. When a threshold voltage is applied to a gate electrode included in a transistor, a conductive channel may be formed in a substrate (i.e., an active region) included in the transistor.

The threshold voltage can be affected by various factors, for example, a difference in work function between the gate of the transistor and the substrate, the amount of charges in a depletion layer in the substrate, capacitance of a dielectric layer located between the gate and the substrate, a thickness of the dielectric layer, an interface potential (i.e., bulk potential), and the like. More specifically, the threshold voltage may be inversely proportional to the capacitance of the dielectric layer included in the transistor, and may be inversely proportional to a concentration of a dipole material included in the dielectric layer.

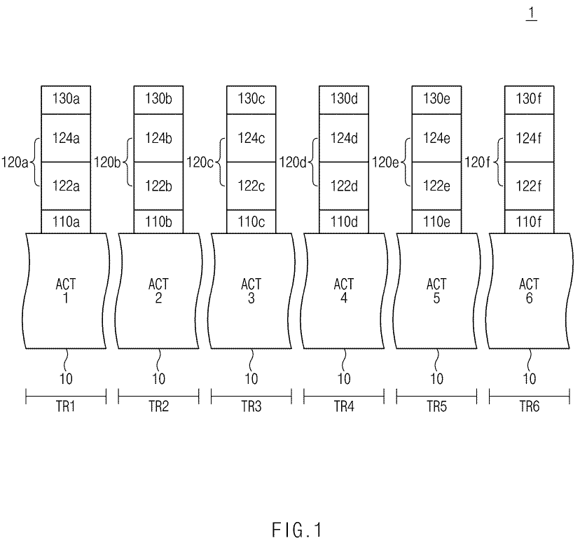

FIG. 1 is a cross-sectional view illustrating a semiconductor device 1 in accordance with an embodiment of the present disclosure.

Referring to FIG. 1, the semiconductor device 1 may include a plurality of transistors (TR1, TR2, TR3, TR4, TR5, TR6) disposed on a semiconductor substrate 10. The semiconductor substrate 10 may include a plurality of active regions (ACT1, ACT2, ACT3, ACT4, ACT5, ACT6) doped with N-type impurities or P-type impurities.

In an embodiment, the first active region (ACT1), the third active region (ACT3), and the fifth active region (ACT5) may be regions doped with N-type impurities, and the second active region (ACT2), the fourth active region (ACT4), and the sixth active region (ACT6) may be regions doped with P-type impurities.

Although not shown in the drawings, the active regions (ACT1, ACT2, ACT3, ACT4, ACT5, ACT6) may include source/drain regions, and the semiconductor substrate 10 may include a plurality of isolation regions formed to isolate the plurality of transistors (TR1, TR2, TR3, TR4, TR5, TR6) from each other.

Interlayer dielectric layers (110a, 110b, 110c, 110d, 110e, 110f) may be formed over the active regions (ACT1, ACT2, ACT3, ACT4, ACT5, ACT6), respectively. Although the interlayer dielectric layers (110a, 110b, 110c, 110d, 110e, 110f) are respectively disposed for the transistors (TR1, TR2, TR3, TR4, TR5, TR6) for convenience of description, other embodiments are also possible, and it should be noted that the interlayer dielectric layers (110a, 110b, 110c, 110d, 110e, 110f) may also be formed as only one layer.

The interlayer dielectric layer (e.g., 110a) may reduce interfacial defects between the semiconductor substrate 10 and the dielectric layer (e.g., 120a). In an embodiment, the interlayer dielectric layer (e.g., 110a) may be formed of a low-permittivity material with a low dielectric constant. For example, the interlayer dielectric layer (e.g., 110a) may include silicon oxide (SiO) or silicon oxynitride (SiON).

A plurality of dielectric layers (120a, 120b, 120c, 120d, 120e, 120f) may be disposed over the interlayer dielectric layers (110a, 110b, 110c, 110d, 110e, 110f), respectively. The dielectric layers (120a, 120b, 120c, 120d, 120e, 120f) may include a dipole material that has a higher dielectric constant (i.e., higher permittivity) than the interlayer dielectric layers (110a, 110b, 110c, 110d, 110e, 110f), respectively. In more detail, the dielectric layer 120a may include a dipole material that has a higher dielectric constant than the interlayer dielectric layer 110a, the dielectric layer 120b may include a dipole material that has a higher dielectric constant than the interlayer dielectric layer 110b, the dielectric layer 120c may include a dipole material that has a higher dielectric constant than the interlayer dielectric layer 110c, the dielectric layer 120d may include a dipole material that has a higher dielectric constant than the interlayer dielectric layer 110d, the dielectric layer 120e may include a dipole material that has a higher dielectric constant than the interlayer dielectric layer 110e, and the dielectric layer 120f may include a dipole material that has a higher dielectric constant than the interlayer dielectric layer 110f. For example, the dipole material may include hafnium (Hf), aluminum (Al), lanthanum (La), zirconium (Zr), scandium (Sc), erbium (Er), etc.

In an embodiment, each of the dielectric layers (120a, 120b, 120c, 120d, 120e, 120f) may be provided as a layered structure containing dielectric materials. For example, the dielectric materials may be formed of any of hafnium oxide (HfO), hafnium silicate (HfSiO), hafnium zirconium oxide (HfZrO), hafnium zirconium silicate (HfSiZrO), hafnium oxynitride (HfON), and hafnium silicate nitride (HfSiON).

More specifically, each dielectric layer (e.g., 120a) may include a plurality of sub-dielectric layers (e.g., 122a and 124a).

In an embodiment, each of the sub-dielectric layers (e.g., 122a and 124a) may include at least one of the above-described dielectric materials (e.g., hafnium oxide (HfO), hafnium silicate (HfSiO), hafnium zirconium oxide (HfZrO), hafnium zirconium silicate (HfSiZrO), hafnium oxynitride (HfON) and hafnium silicate nitride (HfSiON)). There may be differences in diffusivity of the dipole material depending on the types of sub-dielectric materials (e.g., 122a and 124a) included in each dielectric layer (e.g., 120a). In addition, threshold voltages of the transistors (TR1, TR2, TR3, TR4, TR5, TR6) each including the dielectric layer (e.g., 120a) may vary depending on the concentration of the dipole material.

The diffusivity of the dipole material may refer to the degree of diffusion of the dipole material that diffuses into the dielectric material during a drive-in diffusion process such as heat treatment or the like.

When the diffusivity of the dipole material is high, the concentration of the dipole material diffused into the dielectric layer (e.g., 120a) may increase. As the concentration of the dipole material increases, the dielectric constant may increase so that the threshold voltage (Vt) of the transistor (e.g., TR1) including the dielectric layer (e.g., 120a) may decrease.

The dielectric layers (120a, 120b, 120c, 120d, 120e, 120f) respectively included in the transistors may include dipoles of different concentrations, and a difference in threshold voltage (Vt) may occur for each of the transistors (TR1, TR2, TR3, TR4, TR5, TR6) depending on the concentrations of such dipoles.

In an embodiment, the first dielectric layer 120a included in the first transistor (TR1) and the second dielectric layers 120b included in the second transistor (TR2) may include the same dielectric material. A first active region ACT1 included in the first transistor (TR1) may have a different conductivity type from a second active region ACT2 included in the second transistor (TR2).

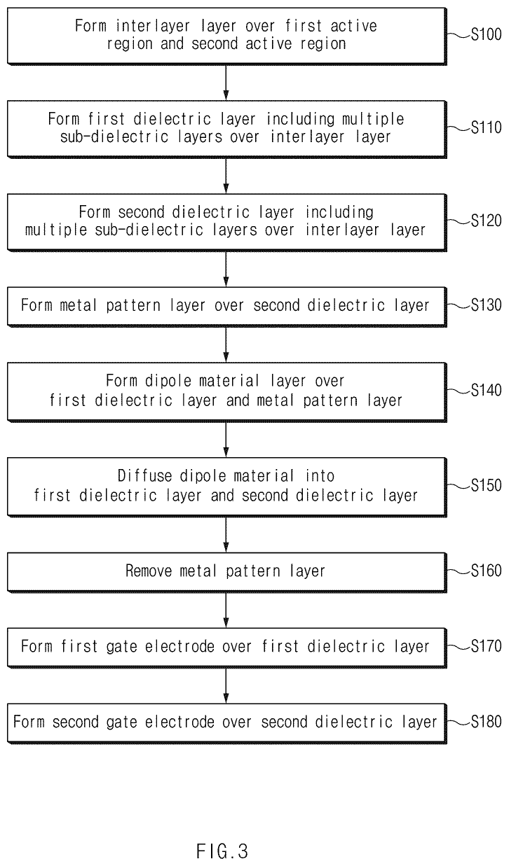

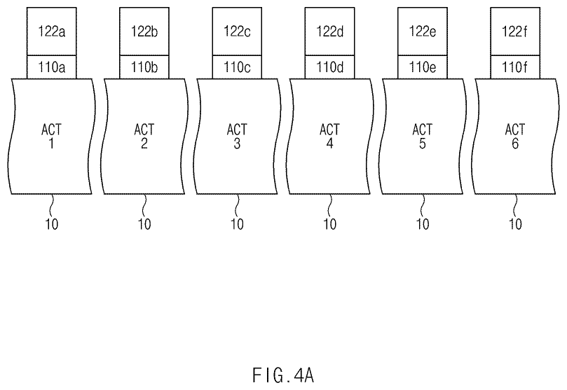

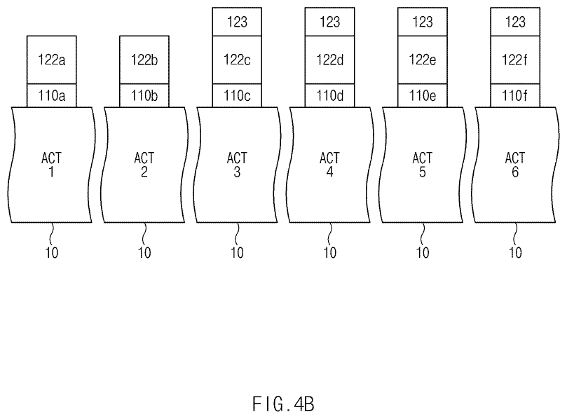

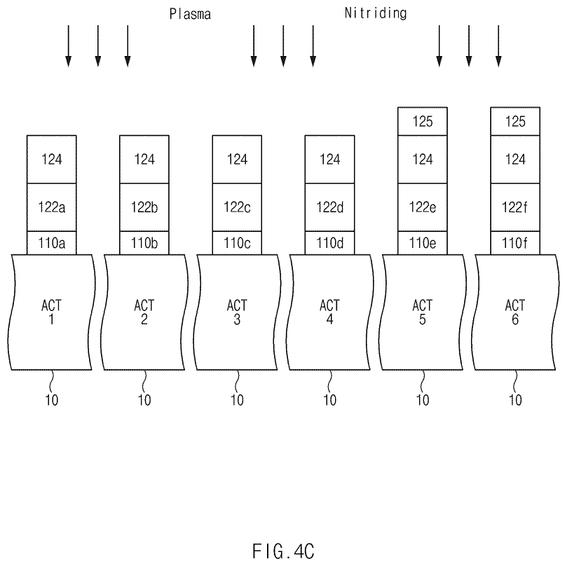

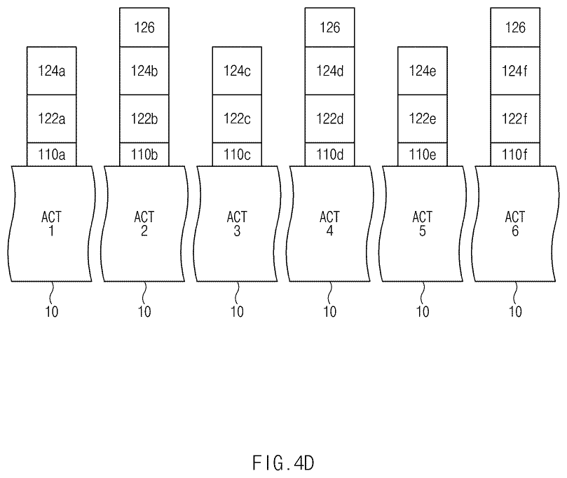

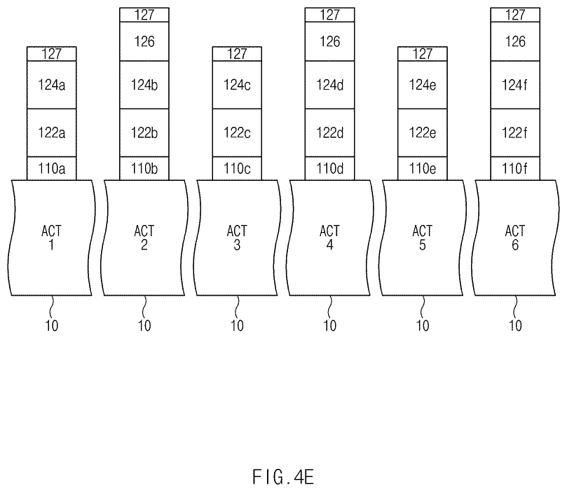

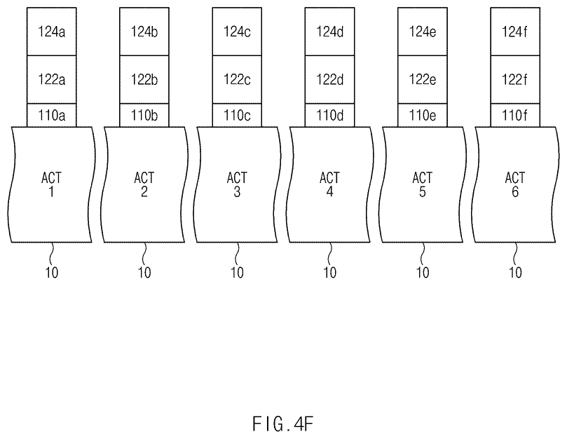

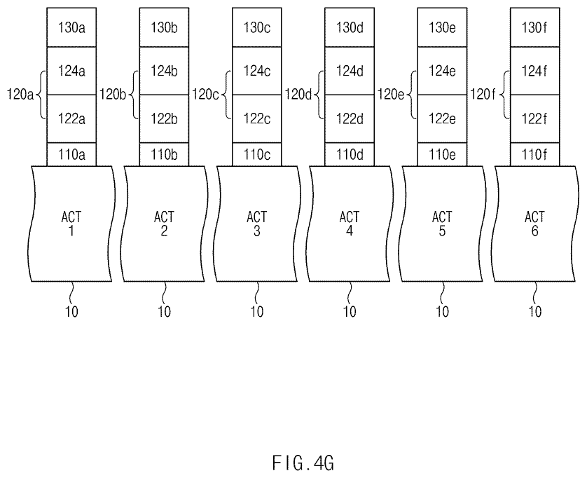

In addition, the dipole concentration of the first dielectric layer 120a may be different from the dipole concentration of the second dielectric layer 120b. A method for controlling the dipole concentration of the first dielectric layer 120a and the dipole concentration of the second dielectric layer 120b will be described in detail with reference to FIGS. 3 and 4A to 4G.

The third dielectric layer 120c included in the third transistor (TR3) and the fourth dielectric layer 120d included in the fourth transistor (TR4) may include the same dielectric material. However, the third dielectric layer 120c may include a different dielectric material from the first dielectric layer 120a.

In an embodiment, the semiconductor device 1 may control a threshold voltage for each of the transistors (TR1, TR2, TR3, TR4, TR5, TR6) by adjusting the concentration of the dielectric materials included in the dielectric layers.

Referring to FIG. 1, the first dielectric layer 120a and the second dielectric layer 120b may include the same dielectric material, the third dielectric layer 120c and the fourth dielectric layer 120d may include the same dielectric material, and the fifth dielectric layer 120e and the sixth dielectric layer 120f may include the same dielectric material. In addition, the first dielectric layer 120a, the third dielectric layer 120c, and the fifth dielectric layer 120e may include different dielectric materials.

Gate electrodes (130a, 130b, 130c, 130d, 130e, 130f) may be disposed over the dielectric layers (120a, 120b, 120c, 120d, 120e, 120f), respectively.

The dielectric layers (120a, 120b, 120c, 120d, 120e, 120f) may be disposed between the gate electrodes (130a, 130b, 130c, 130d, 130e, 130f) and the active regions (ACT1, ACT2, ACT3, ACT4, ACT5, ACT6), respectively. In more detail, the dielectric layer 120a may be disposed between the gate electrode 130a and the active region (ACT1), the dielectric layer 120b may be disposed between the gate electrode 130b and the active region (ACT2), the dielectric layer 120c may be disposed between the gate electrode 130c and the active region (ACT3), the dielectric layer 120d may be disposed between the gate electrode 130d and the active region (ACT4), the dielectric layer 120e may be disposed between the gate electrode 130e and the active region (ACT5), and the dielectric layer 120f may be disposed between the gate electrode 130f and the active region (ACT6).

Each of the gate electrodes (130a, 130b, 130c, 130d, 130e, 130f) may include any one of tungsten (W), copper (Cu), hafnium (Hf), zirconium (Zr), titanium (Ti), tantalum (Ta), aluminum (Al), ruthenium (Ru), palladium (Pd), platinum (Pt), cobalt (Co), nickel (Ni), and conductive metal nitrides, or a combination thereof.

In an embodiment, the first to sixth gate electrodes (130a, 130b, 130c, 130d, 130e, 130f) may include the same conductive materials.

The threshold voltage may be affected by various factors, for example, a difference in work function between the gate electrode (e.g., 130a) and the semiconductor substrate 10, dielectric constants of the interlayer dielectric layer (e.g., 110a) and the dielectric layer (e.g., 120a), and thicknesses of the interlayer dielectric layer (e.g., 110a) and the dielectric layer (e.g., 120a).

The gate electrodes (130a, 130b, 130c, 130d, 130e, 130f) respectively included in the first to sixth transistors (TR1, TR2, TR3, TR4, TR5, TR6) included in the semiconductor device 1 may be formed of the same materials, and may respectively include the interlayer dielectric layers (110a, 110b, 110c, 110d, 110e, 110f) having the same thickness, so that threshold voltages of the first to sixth transistors (TR1, TR2, TR3, TR4, TR5, TR6) can be determined by dielectric constants of the dielectric layers (120a, 120b, 120c, 120d, 120e, 120f).

In an embodiment, the dielectric constants of the dielectric layers (120a, 120b, 120c, 120d, 120e, 120f) may be determined by the concentration of dielectric materials constituting the sub-dielectric layers (e.g., 122a and 124a) and the concentration of dipole materials included in the dielectric layer (e.g., 120a).

In addition, the concentration of such dipole materials may be controlled depending on the types of dielectric materials constituting the sub-dielectric layers (e.g., 122a and 124a).

Hereinafter, a difference in threshold voltage depending on a specific dielectric material included in the dielectric layer will be described.

In an embodiment, the first sub-dielectric layer 122a included in the first dielectric layer 120a and the first sub-dielectric layer 122b included in the second dielectric layer 120b may be formed of hafnium silicate nitride (HfSiON), and the second sub-dielectric layer 124a included in the first dielectric layer 120a and the second sub-dielectric layer 124b included in the second dielectric layer 120b may be formed of hafnium oxynitride (HfON).

In addition, the third sub-dielectric layer 122c included in the third dielectric layer 120c and the third sub-dielectric layer 122d included in the fourth dielectric layer 120d may be formed of hafnium silicate (HfSiO), and the fourth sub-dielectric layer 124c included in third dielectric layer 120c and the fourth sub-dielectric layer 124d included in the fourth dielectric layer 120d may be formed of hafnium oxynitride (HfON).

In addition, the fifth sub-dielectric layer 122e included in the fifth dielectric layer 120e and the fifth sub-dielectric layer 122f included in the sixth dielectric layer 120f may be formed of hafnium silicate (HfSiO), and the sixth sub-dielectric layer 124e included in the fifth dielectric layer 120e and the sixth sub-dielectric layer 124f included in the sixth dielectric layer 120f may be formed of hafnium oxide (HfO).

The dipole material diffused into the dielectric layers (120a, 120b, 120c, 120d, 120e, 120f) may be any one of hafnium (Hf), aluminum (Al), lanthanum (La), zirconium (Zr), scandium (Sc), and erbium (Er).

For example, the same type of dipole materials (e.g., lanthanum) is diffused into each of the dielectric layers (120a, 120b, 120c, 120d, 120e, 120f).

The diffusivity of the dipole material in the dielectric layers (120a, 120b, 120c, 120d, 120e, 120f) may vary depending on the types of dielectric materials included in the dielectric layers (120a, 120b, 120c, 120d, 120e, 120f).

For example, the diffusivity of the dipole material may be determined depending on whether the dielectric material contains nitrogen (N), or may also be determined depending on the concentration of nitrogen (N).

In an embodiment, nitrogen (N) may impede diffusion of the dipole material with respect to the dielectric material, and the concentration of nitrogen (N) and the diffusivity of the dipole material may be inversely proportional to each other.

The concentration of the dipole material included in the first to sixth dielectric layers (120a, 120b, 120c, 120d, 120e, 120f) may vary depending on the difference in diffusivity. More specifically, the concentration of dipole materials included in the first dielectric layer 120a and the second dielectric layer 120b may be lower than the concentration of dipole materials included in the third dielectric layer 120c and the fourth dielectric layer 120d. In addition, the concentration of dipole materials included in the third dielectric layer 120c and the fourth dielectric layer 120d may be lower than the concentration of dipole materials included in the fifth dielectric layer 120e and the sixth dielectric layer 120f.

Accordingly, in association with the first to sixth dielectric layers (120a, 120b, 120c, 120d, 120e, 120f), the threshold voltage of each of the third dielectric layer 120c and the fourth dielectric layer 120d may be lower than the threshold voltage of each of the first dielectric layer 120a and the second dielectric layer 120b. In addition, the threshold voltage of each of the fifth dielectric layer 120e and the sixth dielectric layer 120f may be lower than the threshold voltage of each of the third dielectric layer 120c and the fourth dielectric layer 120d.

A fabrication process of controlling the dielectric layers (120a, 120b, 120c, 120d, 120e, 120f) to have different dielectric materials will be described in detail with reference to FIGS. 4A to 4G.

In an embodiment, a metal pattern layer may be disposed on the dielectric layers (120b, 120d, 120f) formed over the active region doped with P-type impurities, and the dipole material may be diffused into the dielectric layers (120b, 120d, 120f) after passing through the metal pattern layer such that the dipole concentrations of the dielectric layers (e.g., 120a and 120b) containing the same dielectric material can be adjusted to vary. More specifically, a difference in diffusivity of the dipole material may occur depending on the thickness of the metal pattern layer, and a difference in threshold voltage may occur depending on the diffusivity of the dipole material.

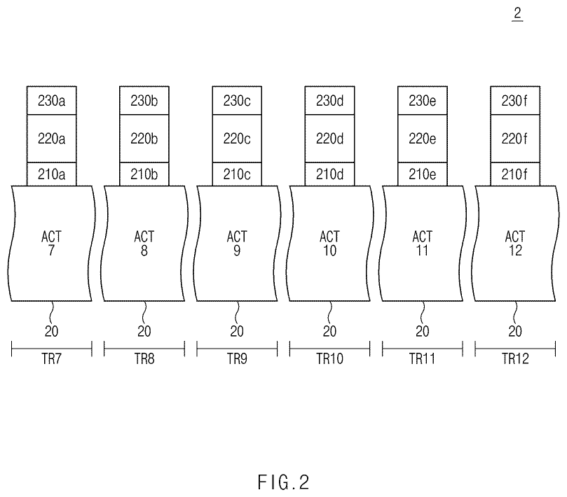

FIG. 2 is a cross-sectional view illustrating a semiconductor device 2 in accordance with another embodiment of the present disclosure.

Referring to FIG. 2, the semiconductor device 2 may include a plurality of transistors (TR7, TR8, TR9, TR10, TR11, TR12) disposed on a semiconductor substrate 20. The semiconductor substrate 20 may include a plurality of active regions (ACT7, ACT8, ACT9, ACT10, ACT11, ACT12) doped with N-type impurities or P-type impurities.

In an embodiment, the seventh active region (ACT7), the ninth active region (ACT9), and the eleventh active region (ACT11) may be regions doped with N-type impurities, and the eighth active region (ACT8), the tenth active region (ACT10), and the twelfth active region (ACT12) may be regions doped with P-type impurities.

Although not shown in the drawings, the active regions (ACT7, ACT8, ACT9, ACT10, ACT11, ACT12) may include source/drain regions, and the semiconductor substrate 20 may include an isolation region formed to isolate the plurality of transistors (TR7, TR8, TR9, TR10, TR11, TR12) from each other.

Interlayer dielectric layers (210a, 210b, 210c, 210d, 210e, 210f) may be formed over the active regions (ACT7, ACT8, ACT9, ACT10, ACT11, ACT12), respectively. Although the interlayer dielectric layers (210a, 210b, 210c, 210d, 210e, 210f) are respectively disposed for the transistors (TR7, TR8, TR9, TR10, TR11, TR12) for convenience of description, other embodiments are also possible, and it should be noted that the interlayer dielectric layers (210a, 210b, 210c, 210d, 210e, 210f) may also be formed as only one layer.

The interlayer dielectric layer (e.g., 210a) may reduce interfacial defects between the semiconductor substrate 20 and the dielectric layer (e.g., 220a). In an embodiment, the interlayer dielectric layer (e.g., 210a) may be formed of a low-permittivity material with a low dielectric constant. For example, the interlayer dielectric layer (e.g., 210a) may include silicon oxide (SiO) or silicon oxynitride (SiON).

A plurality of dielectric layers (220a, 220b, 220c, 220d, 220e, 220f) may be disposed over the interlayer dielectric layers (210a, 210b, 210c, 210d, 210e, 210f), respectively. The dielectric layers (220a, 220b, 220c, 220d, 220e, 220f) may include a dipole material that has a higher dielectric constant (i.e., higher permittivity) than the interlayer dielectric layers (210a, 210b, 210c, 210d, 210e, 210f), respectively. In more detail, the dielectric layer 220a may include a dipole material that has a higher dielectric constant than the interlayer dielectric layer 210a, the dielectric layer 220b may include a dipole material that has a higher dielectric constant than the interlayer dielectric layer 210b, the dielectric layer 220c may include a dipole material that has a higher dielectric constant than the interlayer dielectric layer 210c, the dielectric layer 220d may include a dipole material that has a higher dielectric constant than the interlayer dielectric layer 210d, the dielectric layer 220e may include a dipole material that has a higher dielectric constant than the interlayer dielectric layer 210e, and the dielectric layer 220f may include a dipole material that has a higher dielectric constant than the interlayer dielectric layer 210f. For example, the dipole material may include hafnium (Hf), aluminum (Al), lanthanum (La), zirconium (Zr), scandium (Sc), erbium (Er), etc.

In an embodiment, each of the dielectric layers (220a, 220b, 220c, 220d, 220e, 220f) may be provided as a layered structure containing dielectric materials. For example, the dielectric materials may be formed of any one of hafnium oxide (HfO), hafnium silicate (HfSiO), hafnium zirconium oxide (HfZrO), hafnium zirconium silicate (HfSiZrO), hafnium oxynitride (HfON), and hafnium silicate nitride (HfSiON).

The dielectric layers (220a, 220b, 220c, 220d, 220e, 220f) may be layers containing the same dielectric material, but the concentrations of the dipole materials respectively included in the dielectric layers (220a, 220b, 220c, 220d, 220e, 220f) may be different from each other.

There may be differences in diffusivity of the dipole material depending on the concentration of defects included in the dielectric layer. In addition, threshold voltages of the transistors (TR7, TR8, TR9, TR10, TR11, TR12) each including the dielectric layer (e.g., 220a) may vary depending on the concentration of the dipole material.

When the defect concentration of the dielectric layer is high, the concentration of the dipole material diffused into the dielectric layer may increase. As the concentration of the dipole material increases, the dielectric constant may increase so that the threshold voltage of the transistor (e.g., TR1) including the dielectric layer (e.g., 220a) may decrease.

The dielectric layers (220a, 220b, 220c, 220d, 220e, 220f) respectively included in the transistors may include dipoles of different concentrations, and a difference in threshold voltage (Vt) may occur for each of the transistors (TR7, TR8, TR9, TR10, TR11, TR12) depending on the concentrations of such dipoles.

The defect concentration of the dielectric layers (220a, 220b, 220c, 220d, 220e, 220f) may be controlled by a scavenging process.

The scavenging process may be a heat treatment process in which oxygen included in the dielectric layer (e.g., 220a) is diffused into a defect control layer disposed over the dielectric layer (e.g., 220a) so that the defect concentration caused by oxygen vacancy of the dielectric layer (e.g., 220a) can be controlled.

The defect control layer may include a plurality of sub-control layers. In an embodiment, oxygen diffusion of the dielectric layer (e.g., 220a) with respect to the defect control layer can be controlled depending on the types of sub-control layers to be stacked.

For example, the sub-control layer may be formed of any one of titanium nitride (TiN), titanium aluminide (TiAl), titanium aluminum nitride (TiAIN), and tantalum nitride (TaN). A difference in the degree of oxygen removal during the scavenging process may occur depending on the components and thickness of the sub-control layer. The diffusivity of the dipole material in the dielectric layer (e.g., 220a) can be controlled according to a defect concentration difference caused by oxygen removal.

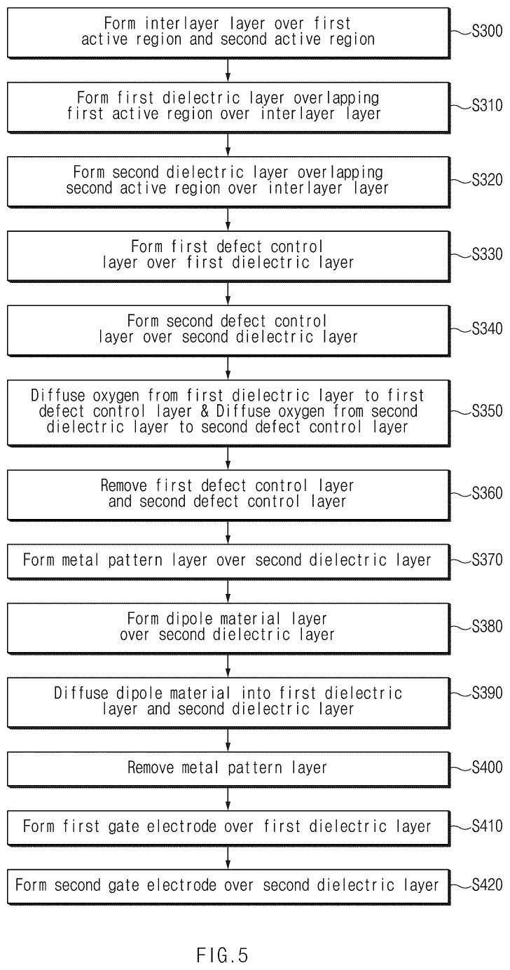

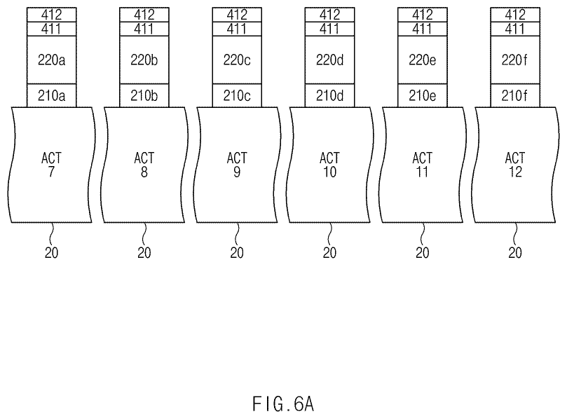

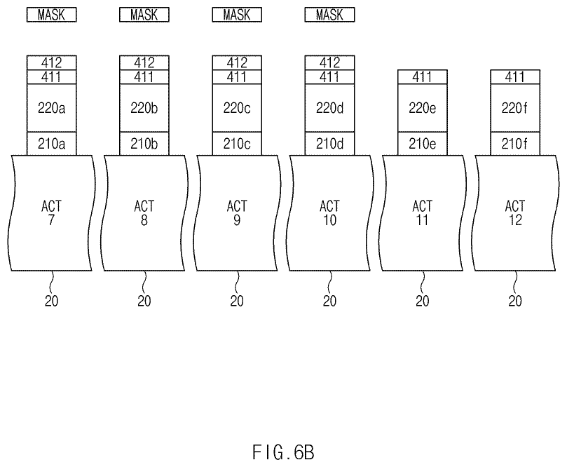

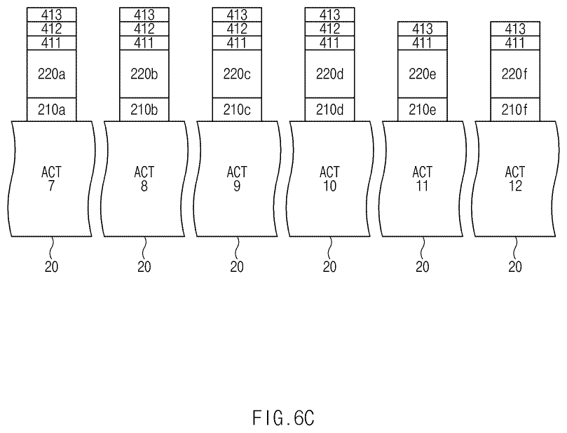

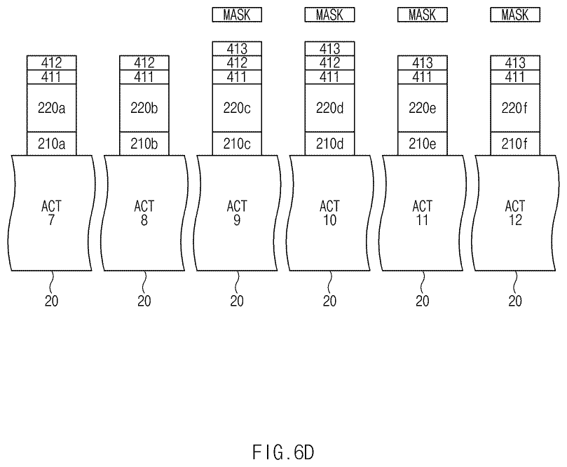

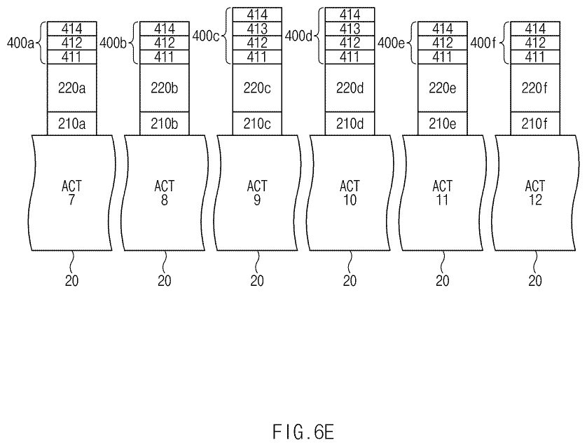

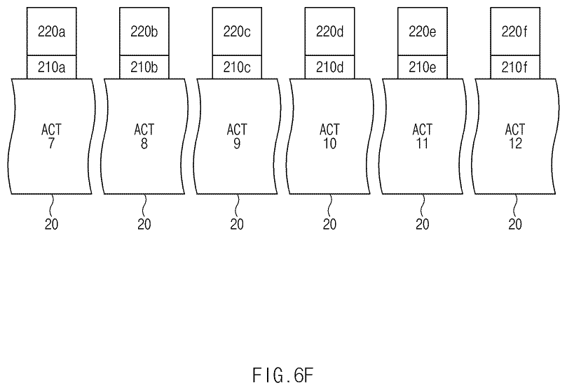

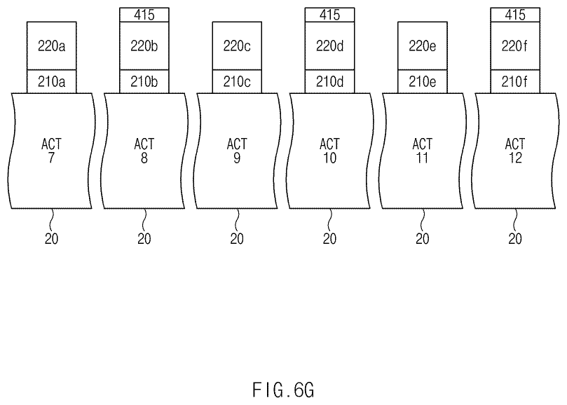

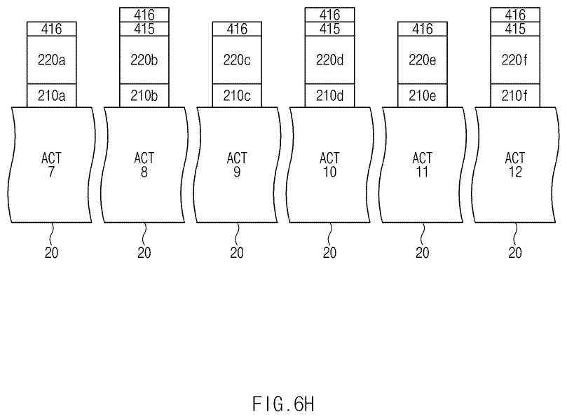

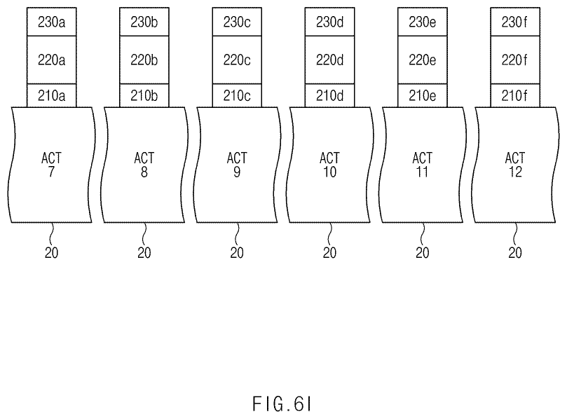

A method for controlling (or adjusting) the defect concentration of the dielectric layers (220a, 220b, 220c, 220d, 220e, 220f) will be described in detail with reference to FIGS. 5 and 6A to 6I.

In an embodiment, the semiconductor device 2 may include a plurality of dielectric layers having different defect concentrations so that the semiconductor device 2 can control (or adjust) the threshold voltages of the transistors (TR7, TR8, TR9, TR10, TR11, TR12).

In FIG. 2, the seventh dielectric layer 220a and the eighth dielectric layer 220b may have the same defect concentration, the ninth dielectric layer 220c and the tenth dielectric layer 220d may have the same defect concentration, and the eleventh dielectric layer (220e) and the twelfth dielectric layer 220f may have the same defect concentration. The dielectric layers (220a, 220b) of two transistors (e.g., TR7, TR8) that are adjacent to each other and have active regions of different impurity types may have the same defect concentration.

Gate electrodes (230a, 230b, 230c, 230d, 230e, 230f) may be disposed over the dielectric layers (220a, 220b, 220c, 220d, 220e, 220f), respectively.

The dielectric layers (220a, 220b, 220c, 220d, 220e, 220f) may be disposed between the gate electrodes (230a, 230b, 230c, 230d, 230e, 230f) and the active regions (ACT7, ACT8, ACT9, ACT10, ACT11, ACT12), respectively. In more detail, the dielectric layer 220a may be disposed between the gate electrode 230a and the active region (ACT7), the dielectric layer 220b may be disposed between the gate electrode 230b and the active region (ACT8), the dielectric layer 220c may be disposed between the gate electrode 230c and the active region (ACT9), the dielectric layer 220d may be disposed between the gate electrode 230d and the active region (ACT10), the dielectric layer 220e may be disposed between the gate electrode 230e and the active region (ACT11), and the dielectric layer 220f may be disposed between the gate electrode 230f and the active region (ACT12).

Each of the gate electrodes (230a, 230b, 230c, 230d, 230e, 230f) may include any one of tungsten (W), copper (Cu), hafnium (Hf), zirconium (Zr), titanium (Ti), tantalum (Ta), aluminum (Al), ruthenium (Ru), palladium (Pd), platinum (Pt), cobalt (Co), nickel (Ni), and conductive metal nitrides, or a combination thereof.

In an embodiment, the seventh to twelfth gate electrodes (230a, 230b, 230c, 230d, 230e, 230f) may include the same conductive materials.

The threshold voltage may be affected by various factors, for example, a difference in work function between the gate electrode (e.g., 230a) and the semiconductor substrate 20, dielectric constants of the interlayer dielectric layer (e.g., 210a) and the dielectric layer (e.g., 220a), and thicknesses of the interlayer dielectric layer (e.g., 210a) and the dielectric layer (e.g., 220a).

The gate electrodes (230a, 230b, 230c, 230d, 230e, 230f) respectively included in the seventh to twelfth transistors (TR7, TR8, TR9, TR10, TR11, TR12) included in the semiconductor device 2 may be formed of the same materials, and may respectively include the interlayer dielectric layers (210a, 210b, 210c, 210d, 210e, 210f) having the same thickness, so that threshold voltages of the seventh to twelfth transistors (TR7, TR8, TR9, TR10, TR11, TR12) can be determined by dielectric constants of the dielectric layers (220a, 220b, 220c, 220d, 220e, 220f).

In an embodiment, the dielectric constants of the dielectric layers (220a, 220b, 220c, 220d, 220e, 220f) may be determined according to the concentration of defects included in each dielectric layer (e.g., 220a) and the concentration of dipole materials diffused into the defects.

In an embodiment, a metal pattern layer may be disposed on the dielectric layers (220b, 220d, 220f) formed over the active region doped with P-type impurities, and the dipole material may be diffused into the dielectric layers (220b, 220d, 220f) after passing through the metal pattern layer such that the dipole concentrations of the dielectric layers (e.g., 220a and 220b) containing the same defect concentration can be adjusted to vary.

FIG. 3 is a flowchart illustrating a method for manufacturing a semiconductor device in accordance with an embodiment of the present disclosure.

FIGS. 4A to 4G are cross-sectional views illustrating a method for manufacturing a semiconductor device in accordance with various embodiments of the present disclosure.

Referring to FIGS. 3 and 4A, the first to sixth active regions (ACT1, ACT2, ACT3, ACT4, ACT5, ACT6) may be defined in the semiconductor substrate 10, and the interlayer dielectric layers (110a, 110b, 110c, 110d, 110e, 110f) may be formed over the active regions (ACT1, ACT2, ACT3, ACT4, ACT5, ACT6), respectively (see S100).

In an embodiment, the semiconductor substrate 10 may be a monocrystalline silicon substrate, an epitaxial substrate formed through epitaxial growth, a silicon-on-insulator (SOI) substrate, or a germanium substrate.

In an embodiment, the first active region (ACT1), the third active region (ACT3), and the fifth active region (ACT5) may be regions doped with N-type impurities, and the second active region (ACT2), the fourth active region (ACT4), and the sixth active region (ACT6) may be regions doped with P-type impurities.

The active regions (ACT1, ACT2, ACT3, ACT4, ACT5, ACT6) may be defined by the isolation region included in the semiconductor substrate 10.

The interlayer dielectric layers (110a, 110b, 110c, 110d, 110e, 110f) may include silicon oxide (SiO) or silicon oxynitride (SiON), and may be formed through the same process.

A pre-lower dielectric layers (120a, 120b, 120c, 120d, 120e, 120f) may be formed over the interlayer dielectric layers (110a, 110b, 110c, 110d, 110e, 110f). For example, the pre-lower dielectric layers (120a, 120b, 120c, 120d, 120e, 120f) may be a layer including hafnium silicate (HfSiO).

Referring to FIGS. 3, 4B, 4C, and 4D, the properties of sub-dielectric layers overlapping different active regions can be adjusted by selectively performing the plasma nitridation process on the pre-lower dielectric layers (120a, 120b, 120c, 120d, 120e, 120f).

Referring to FIG. 4B, a silicon nitride layer 123 may be selectively formed over the pre-lower dielectric layers (120a, 120b, 120c, 120d, 120e, 120f) that overlaps the remaining active regions other than the first active region (ACT1) and the second active region (ACT2), and a plasma nitridation process may be performed.

Nitrogen may be diffused into the first sub-dielectric layers (122a, 122b) that overlap the first active region (ACT1) and the second active region (ACT2) by the plasma nitridation process. Through the above plasma nitridation process, the first sub-dielectric layers (122a, 122b) may include hafnium silicate nitride (HfSiON).

The third sub-dielectric layers (122c, 122d) and the fifth sub-dielectric layers (122e, 122f) may be protected by the silicon nitride layer 123 to prevent nitrogen diffusion. Accordingly, the third sub-dielectric layers (122c, 122d) and the fifth sub-dielectric layers (122e, 122f) may be layers formed of hafnium silicate (HfSiO).

Referring to FIG. 4C, the silicon nitride layer 123 may be removed, and a pre-upper dielectric layer 124 may be formed over the first sub-dielectric layers (122a, 122b), the third sub-dielectric layers (122c, 122d), and the fifth sub-dielectric layers (122e, 122f).

For example, the pre-upper dielectric layer 124 may be a layer containing hafnium oxide (HfO). A silicon nitride layer 125 may be selectively formed over the pre-upper dielectric layer 124, and the plasma nitridation process may then be performed on the silicon nitride layer 125.

As an example, a silicon nitride layer 125 may be formed over the pre-upper dielectric layer 124 that overlaps the fifth active region (ACT5) and the sixth active region (ACT6), and the plasma nitridation process may be performed on the silicon nitride layer 125.

Nitrogen may be diffused into the second sub-dielectric layers (124a, 124b) and the fourth sub-dielectric layers (124c, 124d) by the plasma nitridation process. Here, the second sub-dielectric layer 124a may overlap the first active region (ACT1), the second sub-dielectric layer 124b may overlap the second active region (ACT2), the fourth sub-dielectric layer 124c may overlap the third active region (ACT3), and the fourth sub-dielectric layer 124d may overlap the fourth active region (ACT4). Through the above plasma nitridation process, the second sub-dielectric layers (124a, 124b) and the fourth sub-dielectric layers (124c, 124d) may include hafnium oxynitride (HfON).

The sixth sub-dielectric layers (124e, 124f) may be protected by a silicon nitride layer to prevent nitrogen diffusion. Accordingly, the sixth sub-dielectric layers (124e, 124f) may be hafnium oxide (HfO) layers.

The first to sixth dielectric layers (120a, 120b, 120c, 120d, 120e, 120f) formed to respectively overlap the active regions (ACT1, ACT2, ACT3, ACT4, ACT5, ACT6) included in the semiconductor substrate 10 may be formed through deposition of such dielectric layers and the plasma nitridation process. In addition, the dielectric layers may include the sub-dielectric layers (122a, 122b, 122c, 122d, 122e, 122f, 124a, 124b, 124c, 124d, 124e, 124f). In more detail, the first dielectric layer may include some of the sub-dielectric layers (see S110), and the second dielectric layer may include the remaining sub-dielectric layers (see S120).

Referring to FIG. 4D, a metal pattern layer 126 may be selectively disposed over the dielectric layers (120b, 120d, 120f) located above the active regions (ACT2, ACT4, ACT6) doped with P-type impurities. After the metal pattern layer 126 is formed over the entire active regions (ACT1, ACT2, ACT3, ACT4, ACT5, ACT6), at least a portion of the metal pattern layer 126 may be patterned so that the resultant metal pattern layer 126 can be selectively disposed above the active regions (ACT2, ACT4, ACT6) doped with P-type impurities (see S130).

The metal pattern layer 126 may include a first layer and a second layer that are alternately arranged. Here, the first layer may include any one of titanium nitride (TiN), titanium aluminide (TiAl), titanium aluminum nitride (TiAIN), and tantalum nitride (TaN), and the second layer may include any one of aluminum (Al), niobium (Nb) and tungsten (W).

Referring to FIGS. 3 and 4E, a dipole material layer 127 may be formed over the first dielectric layer 120a, the third dielectric layer 120c, the fifth dielectric layer 120e, and the metal pattern layer 126 (see S140), and dipole materials may be diffused from the dipole material layer 127 into the dielectric layers (120a, 120b, 120c, 120d, 120e, 120f) (see S150).

For example, the dipole material may include hafnium (Hf), aluminum (Al), lanthanum (La), zirconium (Zr), scandium (Sc), erbium (Er), and the like.

The second dielectric layer 120b, the fourth dielectric layer 120d, and the sixth dielectric layer 120f may be formed such that the dipole material can be diffused into the second, fourth and sixth dielectric layers (120b, 120d, 120f) after passing through the metal pattern layer 126.

Accordingly, the second dielectric layer 120b may have a lower dipole material concentration than the first dielectric layer 120a, the fourth dielectric layer 120d may have a lower dipole material concentration than the third dielectric layer 120c, and the sixth dielectric layer 120f may have a lower dipole material concentration than the fifth dielectric layer 120e.

In addition, the diffusivity of the dipole material may be inversely proportional to the concentration of nitrogen contained in the dielectric layer, so that the first dielectric layer 120a and the second dielectric layer 120b may have the lowest dipole concentration, and the fifth dielectric layer 120e and the sixth dielectric layer 120f may have the highest dipole concentration.

Referring to FIGS. 3 and 4F, after the dipole diffusion, the metal pattern layer 126 and the dipole material layer 127 may be removed (see S160).

Since the metal pattern layer 126 is removed, the height of each of the constituent elements included in the semiconductor substrate 10 may be uniformly controlled. However, in order to adjust characteristics (e.g., a work function or the like) of the gate electrode, the metal pattern layer 126 may not be removed. In this case, the gate electrode layer may include the metal pattern layer 126.

Referring to FIGS. 3 and 4G, the gate electrodes (130a, 130b, 130c, 130d, 130e, 130f) may be disposed over the dielectric layers (120a, 120b, 120c, 120d, 120e, 120f), respectively (S170, S180).

Each of the gate electrodes (130a, 130b, 130c, 130d, 130e, 130f) may include any one of tungsten (W), copper (Cu), hafnium (Hf), zirconium (Zr), titanium (Ti), tantalum (Ta), aluminum (Al), ruthenium (Ru), palladium (Pd), platinum (Pt), cobalt (Co), nickel (Ni), and conductive metal nitrides, or a combination thereof.

FIG. 5 is a flowchart illustrating a method for manufacturing a semiconductor device in accordance with another embodiment of the present disclosure.

FIGS. 6A to 6I are cross-sectional views illustrating examples of a method for manufacturing a semiconductor device in accordance with another embodiment of the present disclosure.

Referring to FIGS. 5 and 6A, the seventh to twelfth active regions (ACT7, ACT8, ACT9, ACT10, ACT11, ACT12) may be defined in the semiconductor substrate 20, and the interlayer dielectric layers (210a, 210b, 210c, 210d, 210e, 210f) may be formed over the active regions (ACT7, ACT8, ACT9, ACT10, ACT11, ACT12), respectively (see S300).

In an embodiment, the semiconductor substrate 20 may be a monocrystalline silicon substrate, an epitaxial substrate formed through epitaxial growth, a silicon-on-insulator (SOI) substrate, or a germanium substrate.

In an embodiment, the seventh active region (ACT7), the ninth active region (ACT9), and the eleventh active region (ACT11) may be regions doped with N-type impurities, and the eighth active region (ACT8), the tenth active region (ACT10), and the twelfth active region (ACT12) may be regions doped with P-type impurities.

The active regions (ACT7, ACT8, ACT9, ACT10, ACT11, ACT12) may be defined by the isolation region included in the semiconductor substrate 20.

The interlayer dielectric layers (210a, 210b, 210c, 210d, 210e, 210f) may include silicon oxide (SiO) or silicon oxynitride (SiON), and may be formed through the same process.

The plurality of dielectric layers (220a, 220b, 220c, 220d, 220e, 220f) may be formed over the interlayer dielectric layers (210a, 210b, 210c, 210d, 210e, 210f), respectively (see S310 and S320).

Each of the dielectric layers (220a, 220b, 220c, 220d, 220e, 220f) may be formed as a layered structure containing dielectric materials. For example, the dielectric materials may be formed of any one of hafnium oxide (HfO), hafnium silicate (HfSiO), hafnium zirconium oxide (HfZrO), hafnium zirconium silicate (HfSiZrO), hafnium oxynitride (HfON), and hafnium silicate nitride (HfSiON).

A method for selectively forming a defect control layer including different sub-control layers over the dielectric layers (220a, 220b, 220c, 220d, 220e, 220f) will hereinafter be described with reference to FIGS. 5 and 6A to 6E.

Referring to FIG. 6A, a first metal layer 411 and a second metal layer 412 may be formed over the dielectric layers (220a, 220b, 220c, 220d, 220e, 220f).

For example, the first metal layer 411 may be a titanium nitride (TiN) layer and may be deposited through a physical vapor deposition (PVD) process. Further, the second metal layer 412 may be a titanium aluminide (TiAl) layer and may be deposited through an atomic layer deposition (ALD) process.

A method for adjusting the sub-control layer for each dielectric layer (220a, 220b, 220c, 220d, 220e, 220f) will hereinafter be described with reference to FIG. 6B.

More specifically, masks (MASK) may be disposed to overlap a portion of the semiconductor substrate 20, and the second metal layer 412 may be selectively removed.

Referring to FIG. 6B, masks may be disposed to overlap the seventh active region (ACT7), the eighth active region (ACT8), the ninth active region (ACT9), and the tenth active region (ACT10), and the second metal layer 412 overlapping the eleventh active region (ACT11) and the twelfth active region (ACT12) may be selectively removed.

Referring to FIG. 6C, a third metal layer 413 may be formed over the first metal layer 411 or the second metal layer 412. The third metal layer 413 may be a titanium nitride (TiN) layer and may be deposited through a physical vapor deposition (PVD) process.

Referring to FIG. 6D, masks (MASK) may be disposed to overlap a portion of the semiconductor substrate 20, and the third metal layer 412 may be selectively removed.

Masks (MASK) may overlap the ninth active region (ACT9), the tenth active region (ACT10), the eleventh active region (ACT11), and the twelfth active region (ACT12), and the third metal layer 413 overlapping each of the seventh active region (ACT7) and the eighth active region (ACT8) may be selectively removed.

A method for forming a polysilicon layer 414 over the second metal layer 412 or the third metal layer 413 and performing a scavenging process on the polysilicon layer 414 will hereinafter be described with reference to FIG. 6E.

The defect control layers (400a, 400b, 400c, 400d, 400e, 400f) respectively formed over the dielectric layers (220a, 220b, 220c, 220d, 220e, 220f) may include a plurality of sub-control layers made of different materials (see S330 and S340).

For example, each of the seventh defect control layer 400a overlapping the seventh dielectric layer 220a and the eighth defect control layer 400b overlapping the eighth dielectric layer 220b may include the first metal layer 411, the second metal layer 412, and the polysilicon layer 414 as sub-control layers.

The seventh defect control layer 400a and the eighth defect control layer 400b may include a PVD titanium nitride (TiN) layer and an ALD titanium aluminide (TiAl) layer.

Each of the ninth defect control layer 400c overlapping the ninth dielectric layer 220c and the tenth defect control layer 400d overlapping the tenth dielectric layer 220d may include the first metal layer 411, the second metal layer 412, the third metal layer 413, and the polysilicon layer 414 as sub-control layers.

Each of the ninth defect control layer 400c and the tenth defect control layer 400d may include a PVD titanium nitride (TiN) layer, an ALD titanium aluminide (TiAl) layer, and a PVD titanium nitride (TiN) layer.

Each of the eleventh defect control layer 400e overlapping the eleventh dielectric layer 220e and the twelfth defect control layer 400f overlapping the twelfth dielectric layer 220f may include the first metal layer 411, the third metal layer 413, and the polysilicon layer 414 as sub-control layers.

Each of the eleventh defect control layer 400e and the twelfth defect control layer 400f may include two PVD titanium nitride (TiN) layers.

The scavenging process may refer to a process in which oxygen included in a dielectric layer is diffused into a defect control layer through heat treatment (see S350). As a result, the defect concentration inside the dielectric layer can be controlled depending on the amount of diffused oxygen.

Defects may refer to oxygen vacancies contained in the dielectric layer. As the defect concentration increases, the dipole material can be more easily diffused into the dielectric layer. Therefore, when the defect concentration of the dielectric layer is controlled through the defect control layer, the dipole concentration of the dielectric layer can be controlled. The threshold voltage of each transistor including the dielectric layer can be controlled by adjusting the dipole concentration.

The defect concentration profile of the dielectric layer may vary depending on the type of sub-control layers included in the defect control layer and the thickness of each sub-control layer.

For example, the scavenging effect caused by titanium nitride (TIN) may be greater than the oxygen scavenging effect caused by titanium aluminide (TiAl). If the scavenging effect is large, the amount of oxygen to be removed from the dielectric layer may increase and the defect concentration inside the dielectric layer may also increase, so that the dipole material can easily penetrate into the dielectric layer. Therefore, as the ratio of titanium nitride (TIN) included in the defect control layer increases, the dielectric layer having a lower threshold voltage can be obtained.

In an embodiment, the defect concentration of each of the seventh dielectric layer 220a and the eighth dielectric layer 220b may be lower than the defect concentration of each of the ninth dielectric layer 220c and the tenth dielectric layer 220d, and the defect concentration of each of the ninth dielectric layer 220c and the tenth dielectric layer 220d may be lower than the defect concentration of each of the eleventh dielectric layer 220e and the twelfth dielectric layer 220f. When the defect concentration is low, it is difficult for the dipole material to be diffused into the dielectric layer, so that the threshold voltage may be high.

The polysilicon layer 414 may prevent unintended oxidation that occurs in the defect control layer during the scavenging process.

In some other embodiments, the polysilicon layer may be disposed between the sub-control layers, so that the defect concentration of the dielectric layer due to oxygen removal can be controlled during the scavenging process.

More specifically, when the defect control layer includes polysilicon and titanium nitride (TiN), the higher the ratio of titanium nitride (TiN) compared to polysilicon, the greater the oxygen removal effect during the scavenging process.

In addition, as the titanium nitride (TIN) layer is disposed closer to the dielectric layer, the oxygen removal effect caused by the scavenging process may increase. Therefore, the ratio of polysilicon to titanium nitride (TiN) or the positional relationship between the polysilicon layer and the titanium nitride (TiN) layer may be controlled to adjust the defect concentration of the dielectric layer.

Referring to FIGS. 5 and 6F, the defect control layers (400a, 400b, 400c, 400d, 400e, 400f) may be removed (see S360).

Referring to FIG. 6G, a metal pattern layer 415 may be selectively formed over the dielectric layers (220b, 220d, 220f) disposed above the active regions (ACT8, ACT10, ACT12) doped with P-type impurities.

After the metal pattern layer is formed over the entire active regions (ACT7, ACT8, ACT9, ACT10, ACT11, ACT12), at least a portion of the metal pattern layer 415 may be patterned so that the resultant metal pattern layer 415 can be selectively disposed above the active regions (ACT8, ACT10, ACT12) doped with P-type impurities (see S370).

The metal pattern layer 415 may include a first layer and a second layer that are alternately arranged. Here, the first layer may include any one of titanium nitride (TiN), titanium aluminide (TiAl), titanium aluminum nitride (TiAIN) and tantalum nitride (TaN), and the second layer may include any one of aluminum (Al), niobium (Nb) and tungsten (W).

Referring to FIGS. 5 and 6H, a dipole material layer 416 may be formed over the seventh dielectric layer 220a, the ninth dielectric layer 220c, the eleventh dielectric layer 220e, and the metal pattern layer 415, and dipole materials may be diffused from the dipole material layer 416 to the dielectric layers (220a, 220b, 220c, 220d, 220e, 220f) (see S380 and S390).

For example, the dipole material may include hafnium (Hf), aluminum (Al), lanthanum (La), zirconium (Zr), scandium (Sc), erbium (Er), etc.

The eighth dielectric layer 220b, the tenth dielectric layer 220d, and the twelfth dielectric layer 220f may be formed such that the dipole material can be diffused into the eighth, tenth and twelfth dielectric layers (220b, 220d, 120f) after passing through the metal pattern layer 415. As a result, the eighth dielectric layer 220b may have a lower dipole material concentration than the seventh dielectric layer 220a, the tenth dielectric layer 220d may have a lower dipole material concentration than the ninth dielectric layer 220c, and the twelfth dielectric layer 220f may have a lower dipole material concentration than the eleventh dielectric layer 220e.

In addition, the diffusivity of the dipole material may be proportional to the concentration of defects contained in the dielectric layer, so that the seventh dielectric layer 220a and the eighth dielectric layer 220b may have the lowest dipole concentration, and the eleventh dielectric layer 220e and the twelfth dielectric layer 220f may have the highest dipole concentration.

Referring to FIGS. 5 and 6I, after the dipole diffusion, the metal pattern layer 415 and the dipole material layer 416 may be removed (see S400). Since the metal pattern layer 415 is removed, the height of each of the constituent elements included in the semiconductor substrate 20 may be uniformly controlled. However, in order to adjust characteristics (e.g., a work function or the like) of the gate electrode, the metal pattern layer 415 may not be removed. In this case, the gate electrode layer may include the metal pattern layer 415.

Thereafter, gate electrodes (230a, 230b, 230c, 230d, 230e, 230f) may be disposed over the dielectric layers (220a, 220b, 220c, 220d, 220e, 220f), respectively (see S410 and S420).

Each of the gate electrodes (230a, 230b, 230c, 230d, 230e, 230f) may include any one of tungsten (W), copper (Cu), hafnium (Hf), zirconium (Zr), titanium (Ti), tantalum (Ta), aluminum (Al), ruthenium (Ru), palladium (Pd), platinum (Pt), cobalt (Co), nickel (Ni), and conductive metal nitrides, or a combination thereof.

As is apparent from the above description, the semiconductor device in accordance with embodiments of the present disclosure can adjust a threshold voltage of each transistor by adjusting the properties of a dielectric layer.

The embodiments of the present disclosure may provide a variety of effects capable of being directly or indirectly recognized through the above-mentioned present disclosure.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments of the present disclosure have been described, it should be understood that modifications and/or enhancements to the disclosed embodiments and other embodiments can be devised based on what is described and/or illustrated in the present disclosure. Furthermore, the embodiments may be combined to form additional embodiments.

What is claimed is:

1. A semiconductor device comprising:
a semiconductor substrate including a first active region and a second active region;
a first dielectric layer disposed over the first active region;
a second dielectric layer disposed over the second active region;
a first gate electrode disposed over the first dielectric layer; and
a second gate electrode disposed over the second dielectric layer,
wherein:
the first active region and the second active region have different conductivity types,
the first dielectric layer and the second dielectric layer include a same dielectric material, and
dipole concentration of the first dielectric layer is different from dipole concentration of the second dielectric layer.

2. The semiconductor device according to claim 1, wherein each of the first dielectric layer and the second dielectric layer includes:
a first sub-dielectric layer; and
a second sub-dielectric layer disposed over the first sub-dielectric layer.

3. The semiconductor device according to claim 2, wherein the first sub-dielectric layer and the second sub-dielectric layer have different silicon concentrations.

4. The semiconductor device according to claim 2, wherein the first sub-dielectric layer and the second sub-dielectric layer have different nitrogen concentrations.

5. The semiconductor device according to claim 1, wherein each of the first dielectric layer and the second dielectric layer include a defect in which dipole diffusion occurs.

6. The semiconductor device according to claim 5, wherein concentration of the defect of the first dielectric layer and concentration of the defect of the second dielectric layer are controlled by heat treatment.

7. The semiconductor device according to claim 1, wherein the first dielectric layer includes a dipole material that is diffused from an upper portion of the first dielectric layer to the inside of the first dielectric layer.

8. The semiconductor device according to claim 7, wherein the dipole material includes at least one of hafnium (Hf), aluminum (Al), lanthanum (La), zirconium (Zr), scandium (Sc), and erbium (Er).

9. The semiconductor device according to claim 1, wherein the semiconductor substrate further includes:
a third active region and a fourth active region;
a third gate electrode disposed to overlap the third active region;
a fourth gate electrode disposed to overlap the fourth active region;
a third dielectric layer disposed between the third active region and the third gate electrode; and
a fourth dielectric layer disposed between the fourth active region and the fourth gate electrode,
wherein:
the third active region and the fourth active region have different conductivity types,
the first active region and the third active region have a same conductivity type, and
the third dielectric layer and the fourth dielectric layer include a same dielectric material.

10. The semiconductor device according to claim 9, wherein dipole concentration of the third dielectric layer is different from dipole concentration of the fourth dielectric layer.

11. The semiconductor device according to claim 9, wherein the first dielectric layer and the third dielectric layer include different dielectric materials.

12. The semiconductor device according to claim 9, wherein each of the third dielectric layer and the fourth dielectric layer includes:
a third sub-dielectric layer; and
a fourth sub-dielectric layer disposed over the third sub-dielectric layer.

13. The semiconductor device according to claim 9, wherein the first dielectric layer, the second dielectric layer, the third dielectric layer, and the fourth dielectric layer include a same dielectric material.

14. A method for manufacturing a semiconductor device, the method comprising:
forming a first dielectric layer over a first active region included in a semiconductor substrate;
forming a second dielectric layer over a second active region included in the semiconductor substrate;
forming a metal pattern layer over the second dielectric layer;
forming a dipole material layer over the first dielectric layer and the metal pattern layer;
diffusing dipole material from the dipole material layer to the first dielectric layer and the second dielectric layer;
forming a first gate electrode overlapping the first dielectric layer; and
forming a second gate electrode overlapping the second dielectric layer,
wherein:
the first dielectric layer and the second dielectric layer include a same dielectric material, and
the first active region and the second active region have different conductivity types.

15. The method according to claim 14, further comprising forming an interlayer dielectric layer over the first active region and the second active region,
wherein the forming the first dielectric layer includes:
forming a first sub-dielectric layer overlapping the interlayer dielectric layer; and
forming a second sub-dielectric layer overlapping the first sub-dielectric layer, and
wherein the forming the second dielectric layer includes:
forming the first sub-dielectric layer overlapping the interlayer dielectric layer; and
forming the second sub-dielectric layer overlapping the first sub-dielectric layer.

16. The method according to claim 14, further comprising:
forming a first defect control layer over the first dielectric layer;
forming a second defect control layer over the second dielectric layer;
performing heat treatment to control defect concentration of the first dielectric layer and defect concentration of the second dielectric layer; and
removing the first defect control layer and the second defect control layer.

17. The method according to claim 16, wherein the first defect control layer or the second defect control layer includes a plurality of sub-control layers.

18. The method according to claim 17, wherein the plurality of sub-control layers include at least one of titanium nitride (TN), titanium aluminide (TiAl), and polysilicon (Si).

19. The method according to claim 14, further comprising removing the metal pattern layer.

20. The method according to claim 14, wherein the dipole material includes at least one of hafnium (Hf), aluminum (Al), lanthanum (La), zirconium (Zr), scandium (Sc), and erbium (Er).
